(19) United States
(12) Patent Application Publication
(10) Pub. No.: US 2017/0263863 A1
(43) Pub. Date: Sep. 14, 2017

(54) PHASE CHANGE MEMORY HAVING A COMPOSITE MEMORY ELEMENT

(71) Applicants: MACRONIX INTERNATIONAL CO., LTD., Hsinchu (TW); INTERNATIONAL BUSINESS MACHINES CORPORATION, Armonk, NY (US)

(72) Inventors: Hsiang-Lan LUNG, ARDSLEY, NY (US); Huai-Yu CHENG, WHITE PLAINS, NY (US); Matthew J. BRIGHTSKY, POUND RIDGE, NY (US)

(73) Assignees: MACRONIX INTERNATIONAL CO., LTD., HSINCHU (TW); INTERNATIONAL BUSINESS MACHINES CORPORATION, ARMONK, NY (US)

(21) Appl. No.: 15/069,712

(22) Filed: Mar. 14, 2016

(51) Int. Cl. H01L 45/00; H01L 27/24

(52) U.S. Cl. CPC H01L 45/06; H01L 45/1233; H01L 45/1253; H01L 45/1625; H01L 45/144; H01L 27/2463

(57) ABSTRACT

A phase change memory device with a composite memory element includes first and second layers of memory materials, and the composite memory element has a basis phase change material, such as a chalcogenide, and one or more additives, where the first layer of memory material is formed using oxygen-free atmosphere and the second layer of memory material is formed using oxygen-containing atmosphere. The use of “oxygen-free” atmosphere can prevent oxidation at the electrode surface of the first electrode.

### PARTIES TO A JOINT RESEARCH AGREEMENT

International Business Machines Corporation, a New York corporation, and Macronix International Corporation, Ltd., a Taiwan corporation are parties to a Joint Research Agreement.

### BACKGROUND

Technical Field

The present invention relates to memory devices based on phase change materials including chalcogenide materials, and methods for manufacturing such devices.

Description of Related Art

Phase change based memory materials, like chalcogenide based materials and similar materials, can be caused to change between an amorphous phase and a crystalline phase by application of electrical current at levels suitable for implementation in integrated circuits. The amorphous phase is characterized by higher electrical resistivity than the crystalline phase, which can be readily read to indicate data. These properties have generated interest in using programmable resistive material to form non-volatile memory circuits, which can be read and written with random access.

The change from the amorphous to the crystalline phase is generally a lower current operation. The change from crystalline to amorphous, referred to as reset herein, is generally a higher current operation, which includes a short high current density pulse to melt or breakdown the crystalline structure, after which the phase change material cools quickly, quenching the phase change process and allowing at least a portion of the phase change material to stabilize in the amorphous phase.

Phase change materials can comprise chalcogenides combined with additives to modify conductivity, transition temperature, melting temperature, and other properties of the material. Combining phase change materials with additives is sometimes referred to as “doping with impurities” or adding “dopants.” The terms “additive,” “dopant” or “impurity” can be used interchangeably in connection with this specification.

Representative additives used with chalcogenides include nitrogen, silicon, oxygen, silicon oxide, silicon nitride, copper, silver, gold, aluminum, aluminum oxide, tantalum, tantalum oxide, tantalum nitride, titanium and titanium oxide.

When the doped phase change material can contain oxygen in an elemental state or in oxide compounds. Doping oxygen into the memory material causes formation of a thin oxidized film of first electrode material between the doped phase change material and the first electrode. Such oxidized film of first electrode material can result in device failure and decrease yield. It could otherwise increase the magnitude of currents needed for set and reset operations and lead to long set programming speed and high threshold voltage issues. Further, during operations, repeated high set and reset currents can cause damage to the phase change material, which can lead to device failure and limit the cycle endurance of the cell.

It is therefore desirable to provide memory cells using oxygen-containing memory materials, while addressing the yield, endurance, fast switching and other issues.

### SUMMARY OF THE INVENTION

A memory device is described that comprises a phase change memory cell having a composite memory element including oxygen, and oxidation-free electrode surface.

A method of manufacturing a memory device is described herein including forming a first electrode having an electrode surface; depositing a composite memory element including forming a first layer of memory material using oxygen-free atmosphere in a chamber and forming a second layer of memory material on the first layer in the chamber using oxygen-containing atmosphere; and forming a second electrode on the composite memory element. The first and second layers of memory materials can comprise a chalcogenide with one or more additives selected from a group including silicon, nitrogen and carbon, and the second layer of memory material further comprises oxygen. The oxygen-free atmosphere used in said forming the first layer prevents the electrode surface of the first electrode from oxidation.

A method of manufacturing a memory device is also described herein including forming a first electrode; depositing a first layer of memory material on the first electrode by sputtering in an oxygen-free atmosphere; and depositing a second layer of memory material on the first layer of memory material by sputtering in an atmosphere including an oxygen source gas, such as oxygen or an oxygen carrier. The first electrode can be formed in a dielectric layer having an oxide-free surface exposed at the beginning of the step of forming the first layer.

A phase change memory device is described herein with a composite memory element that includes a phase change material with an additive, the additive comprising oxygen. For example, the composite memory element can include first and second layers of GST memory materials, where the second layer includes an additive of silicon oxide. The first layer of memory material can be formed using oxygen-free atmosphere and the second layer of memory material is formed using oxygen-containing atmosphere. The use of “oxygen-free” atmosphere prevents oxidation of the electrode surface of the first electrode. Such composite memory element maintains the advantage of oxygen or silicon oxide additives but avoids oxidizing the first electrode.

An integrated circuit memory device is described herein comprises an array of memory cells and each of the memory cells in the array comprises a first electrode having an electrode surface of an electrode material, a second electrode and a composite memory element between the first and second electrodes. The composite memory element including oxygen, and the electrode surface is substantially free of oxides of the electrode material.

In one example, a GST phase change material is used as a basis memory material, and silicon is used as an additive in the first layer, while silicon dioxide is used as an additive in the second layer.

This provides a cell that has improved contact between the first electrode and the first layer in the composite memory element. Also, the presence of silicon oxide doping in the second layer improves endurance over set/reset cycling, while resisting void formation.

Other aspects and advantages of the present invention can be seen on review of the drawings, and the detailed description.

### BRIEF DESCRIPTION OF THE DRAWINGS

FIG. 1 is a simplified cross-section of a memory cell having layers which are subject to different manufacturing conditions according to one embodiment.

FIG. 2 is a transmission electron microscopy (TEM) image illustrating a cross-section of a memory cell as described herein.

FIG. 3 is a diagram showing relative concentration profiles of a basis material and additives in the memory cell of FIG. 2.

FIG. 4 is a simplified diagram of a system for forming a SiOₓ-doped GeSbTe memory material through sputtering.

FIG. 5 is a simplified diagram of an alternative sputtering system used in a method of creating a SiOₓ-doped GeSbTe memory device.

FIG. 6 illustrates a process flow for forming a composite memory element of Si-doped and SiOₓ-doped GeSbTe phase change materials using either of the previously described sputtering systems.

FIG. 7 illustrates a manufacturing process for manufacturing a memory cell having the composite memory element formed in FIG. 6.

FIG. 8 is a schematic diagram of a second embodiment of a memory cell having a phase change memory element with a composite memory element.

FIG. 9 is a schematic diagram of a third embodiment of a memory cell having a phase change memory element with a composite memory element.

FIG. 10 is a schematic diagram of an integrated circuit memory device including an array of phase change memory cells having a composite memory element.

### DETAILED DESCRIPTION

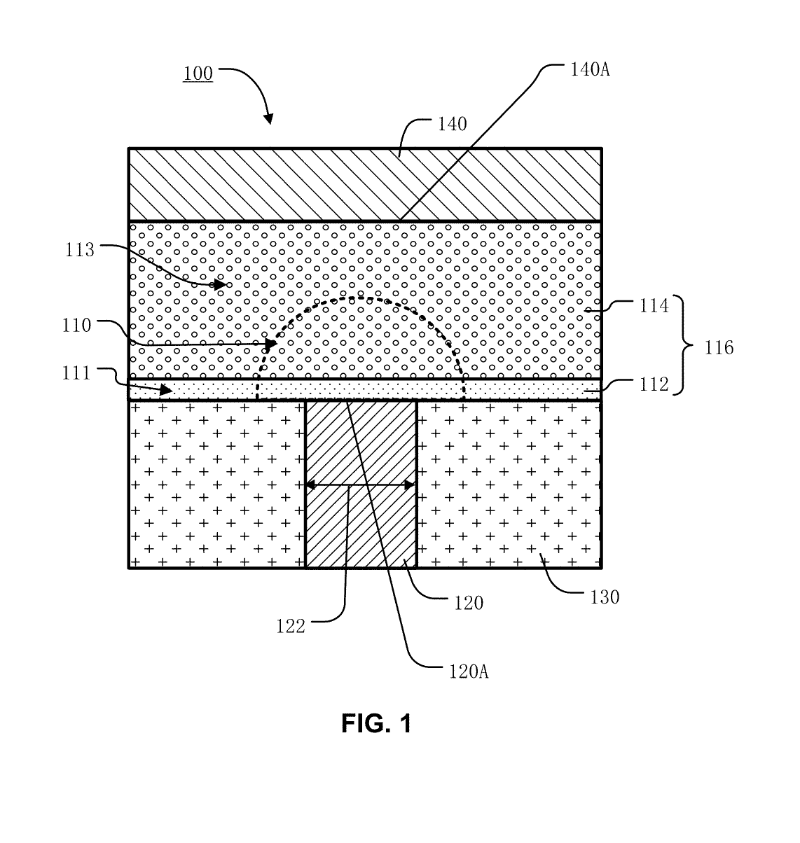

A detailed description of embodiments of the present invention is provided with reference to the FIGS. 1-10.

FIG. 1 illustrates a cross-sectional view of a memory cell 100 including a memory element 116 comprising a first layer 112 of phase change material and a second layer 114 of phase change material containing oxygen. The memory cell 100 includes a first electrode 120 (or bottom electrode) extending through dielectric 130 and having an electrode surface 120A in contact with a bottom surface of the first layer 112 of phase change material, and a second electrode 140 (or top electrode) with an electrode surface 140A in contact with the second layer 114. In alternative embodiments, there may be additional layer or layers of phase change material between the second layer 114 and the electrode surface of the second electrode. The first and second electrodes 120, 140 are conductive materials and may comprise electrode surfaces of, for example, TiN or TaN or other conductive materials compatible with the phase change materials utilized. For example, the first and second electrodes 120, 140 may comprise electrode surfaces of W, WN, TiAlN or TaAlN.

In the illustrated embodiment the dielectric 130 comprises silicon nitride SiₓN_{y}. Thus, the dielectric has an oxide-free surface exposed at the beginning of a step of forming the first layer 112. In the illustrated embodiment, the dielectric 130 is a single layer. In other embodiments, the dielectric 130 can be a multilayer interlayer dielectric of having a silicon nitride top layer, or a top layer of other oxide free materials.

Alternatively, other dielectric materials, such as silicon oxide SiOₓ, siilcon oxynitride SiOₓN_{y}, and other materials suitable for use as inter-layer dielectrics in the memory device may be used.

As can be seen in FIG. 1, the relatively narrow width 122 (which in some embodiments is a diameter) of first electrode 120 results in an area of the electrode surface in contact with the and composite memory element 116 that is less than the area of contact between composite memory element 116 and the electrode surface of the second electrode 140. Thus current is concentrated in the portion of composite memory element 116 adjacent first electrode 120, resulting in active region 110, across the first and second layers of phase change materials and in contact with or near first electrode 120, as shown. The first layer 112 can be thin, relative to the overall thickness of the active region 110, so that majority of the active region 110 is in the second layer 114 of memory material. Composite memory element 116 also includes inactive regions 111 and 113, outside the active region 110, which is inactive in the sense that it does not undergo phase transitions during operation.

In an embodiment described herein, the first and second layers 212, 214 are Si-doped Ge₂Sb₂Te₅ and SiOₓ-doped Ge₂Sb₂Te₅, respectively. Other chalcogenides and other additives may be used as well.

In other embodiments, other basis phase change materials may include a material referred to herein as GST, which has the basic formula GeₓSb_{y}Te_{z}, where x, y and z are integers that can be 2, 2, and 5, and can be other than 2, 2 and 5. Also, the oxygen in the second layer 114 can comprise other oxides or elemental oxygen.

Other basis phase change materials other than GeSbTe-based materials can also be used, including GaSbTe system, which can be described as GaₓSb_{y}Te_{z} and x, y, z are integers. In yet other embodiments, oxygen containing additives in the second layer 114 can include one or more of silicon oxynitrides, silicon oxide and silicon oxycarbides.

In general, examples of oxygen containing additives in the second layer 114 include oxygen and/or combinations of oxygen with one or more elements selecting from the group consisting of Si, N, C, Ge, Ga, Cr, Ti, W, Mo, Al, Ta, Cu, Pt, Ir, La, Ni, N, O, and Ru in the form of oxides, in elemental form, in other compound forms or in mixtures thereof.

The electrode surface 120A of the first electrode 120 is the part of the first electrode in contact with the phase change material, and at which the transition between the electrode and the memory material is found. As described herein, the electrode surface 120A is substantially free of oxides of the material of the electrode surface. For the purposes of this description, substantially free means that the electrode surface is not oxidized during the formation of the first layer 112 of memory material, and the first layer 112 inhibits oxidation of the electrode surface 120A during formation of the second layer 114, even in the presence of the oxygen carrier used in formation of the second layer 114. As a result, oxidation of the electrode surface is prevented or little or no oxidation occurs. One benchmark for considering the electrode surface to be substantially free of oxides is using EELS (electron energy loss spectroscopy) the measured atomic percentage of oxygen at the interface should be less than 1 atomic %, in at least several measurement locations on the interface, which is near the reliable detection limits of EELS technology.

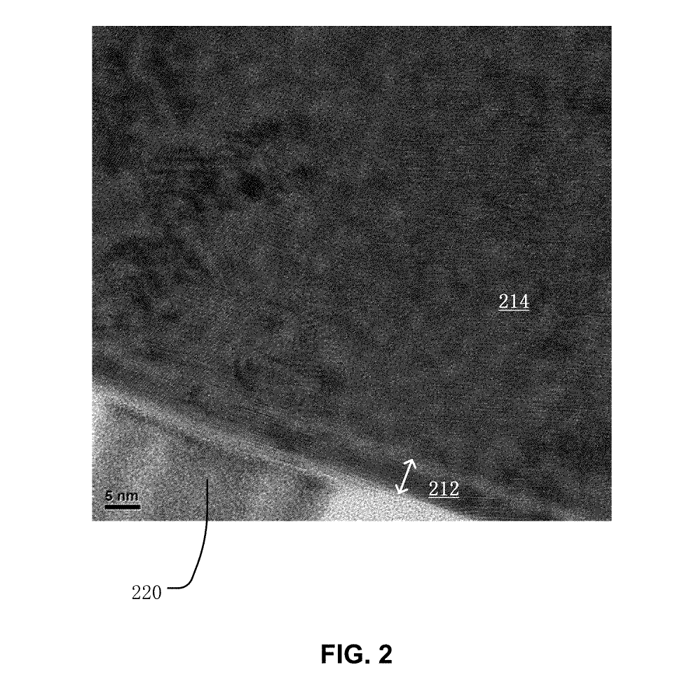

FIG. 2 is a transmission electron microscopy (TEM) image illustrating a cross-section of a memory cell as described in FIG. 1. The basis material of first and second layer 212, 214 of phase change materials in this example comprises Ge₂Sb₂Te₅. The basis material can be defined as the combination of elements selected as the phase change material. As additives are combined, the concentrations of the elements of the basis material may not change relative to one another. In this example, with regard to first layer 212, the O concentration can be a level of at or near 0 at % adjacent the first electrode 220. Also, no oxidized layer of the electrode surface material of first electrode 220 is formed between first electrode 220 and first layer 212. With regard to second layer 214, the O concentration can increase to about 10-30 at % in the second layer 214 of phase change material. In one example, the sputter target comprises Si, Ge, Sb, and Te with a predetermined composition. The first layer 212 may comprise substantially the same composition where no additional additive is added in the formation of first layer 212. While oxygen gas is used as a reactive gas, the silicon and oxygen components of silicon dioxide can have a combined concentration in a range of about 15 to 35 at % in the second layer 214. The relative component concentrations of Si, Ge, Sb, and Te in the first layer of the phase change material can be substantially the same as those in the second layer of the phase change material. Of course, other concentrations and kinds of additives can be used.

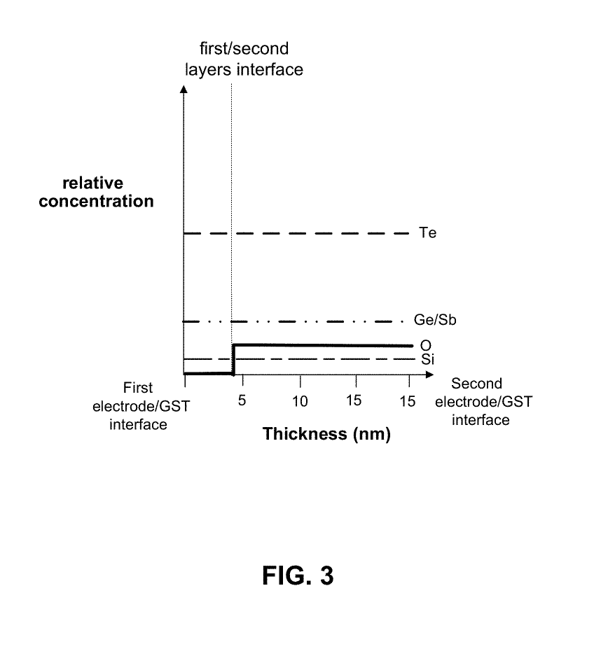

FIG. 3 is a heuristic diagram showing relative concentration profiles of a basis material and additives in the memory cell of FIG. 2. Although the materials can migrate after deposition, one can understand that as deposited, the first layer includes relative concentrations of Si, Te, and Ge/Sb at the levels relative to each other without oxygen, and the second layer includes the same relative concentrations (ignoring the oxygen concentration). The oxygen concentration increases at the interface between the first and second layers to about twice the concentration of the silicon for the example in which the additive is considered to be silicon dioxide.

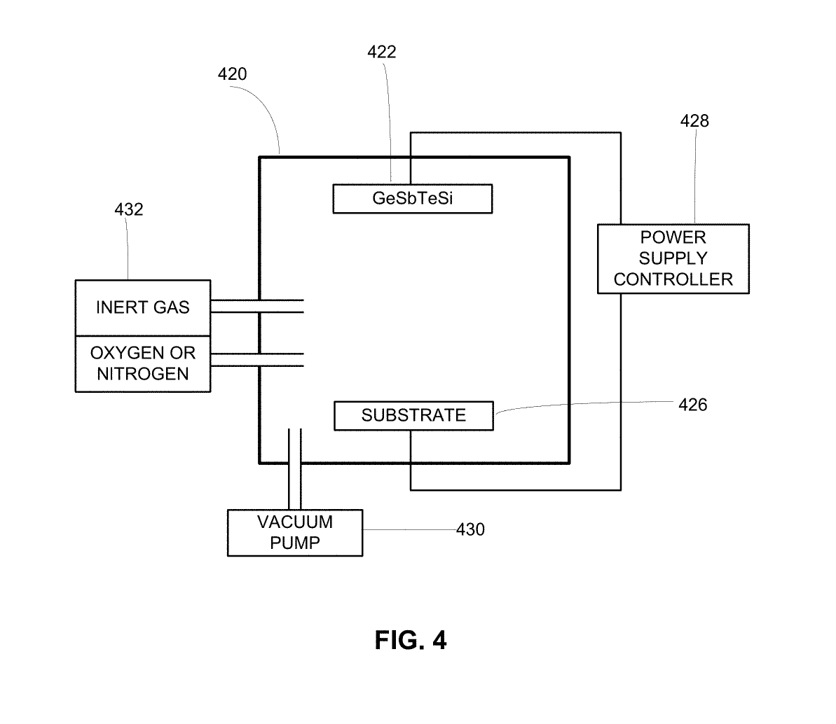

FIG. 4 is a simplified diagram of a method of creating a SiOₓ-doped GST memory material through a sputtering system. The sputtering system includes a chamber 420 in which a Si-GST sputter target 422 (or a set of targets composed of the materials separately or in various combinations) and a substrate 426 are mounted. The sputter target 422 and substrate 326 are coupled to a power supply and controller 428 that are used to apply bias voltages during the sputtering process. Bias voltages applied can be DC, pulsed DC, radio frequency, and combinations thereof, and turned on and off and modulated by the controller, as suits a particular sputtering process. The sputter chamber 420 is equipped with a vacuum pump 430 or other means for evacuating the chamber and removing exhaust gases. Also, the chamber is configured with a gas source 432, by which the atmosphere in the chamber is controlled. In one embodiment of the present invention the gas source 432 is a source for an inert gas such as argon. In addition, some embodiments may include a gas source 432 of the reaction gas, such as oxygen or nitrogen in the examples for use in causing addition of other components in the bulk Si-GST. If one target may be utilized, the composition of Si-GST material that is deposited onto substrate 426 comes from a Si-GST target.

A collimator (not shown) can be used when sputtering a substrate that includes high aspect ratio features, to improve the uniformity of coverage over the high aspect ratio features, and for other reasons. Some sputtering systems have the ability to move a collimator into and out of the sputtering chamber as needed.

It will be appreciated that this is a simplified diagram sufficient for heuristic purposes of description herein. Sputter chambers are standard equipment in semiconductor manufacturing factories, and available from a variety of commercial sources.

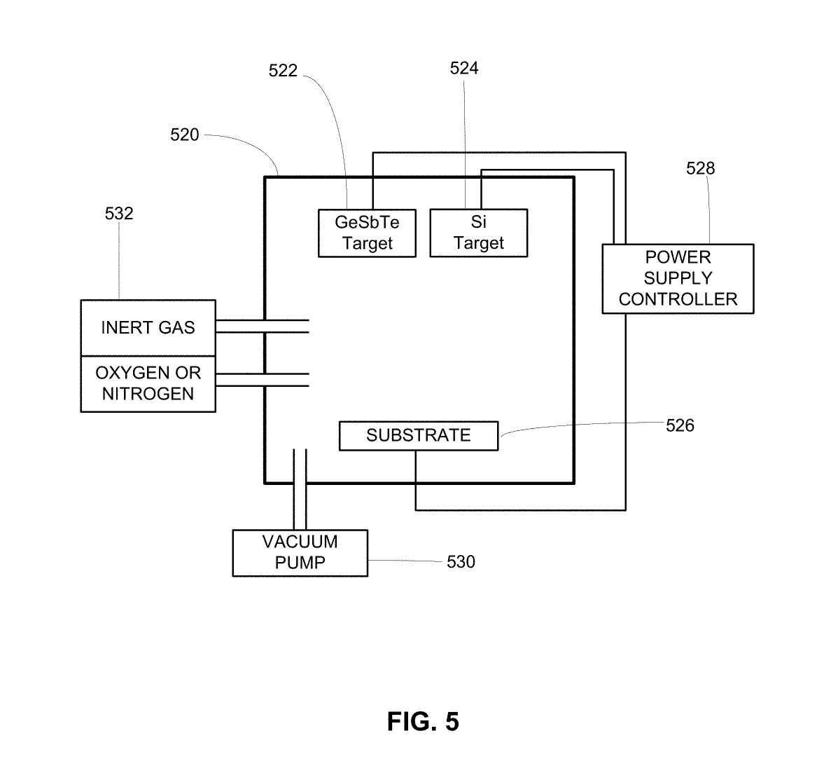

In yet another embodiment, as shown in FIG. 5, to form the SiOₓ-doped GST material, two separate sputter targets 522, 524 are included in the chamber 520. FIG. 5 is a simplified diagram of an alternative sputtering system. FIG. 5 differs from the sputtering system of FIG. 4 in that a separate Si sputtering target is utilized.

In this example, by controlling the power applied to the silicon target differently during formation of the first and second layers, the first layer may have a Si concentration substantially the same as or different than the second layer.

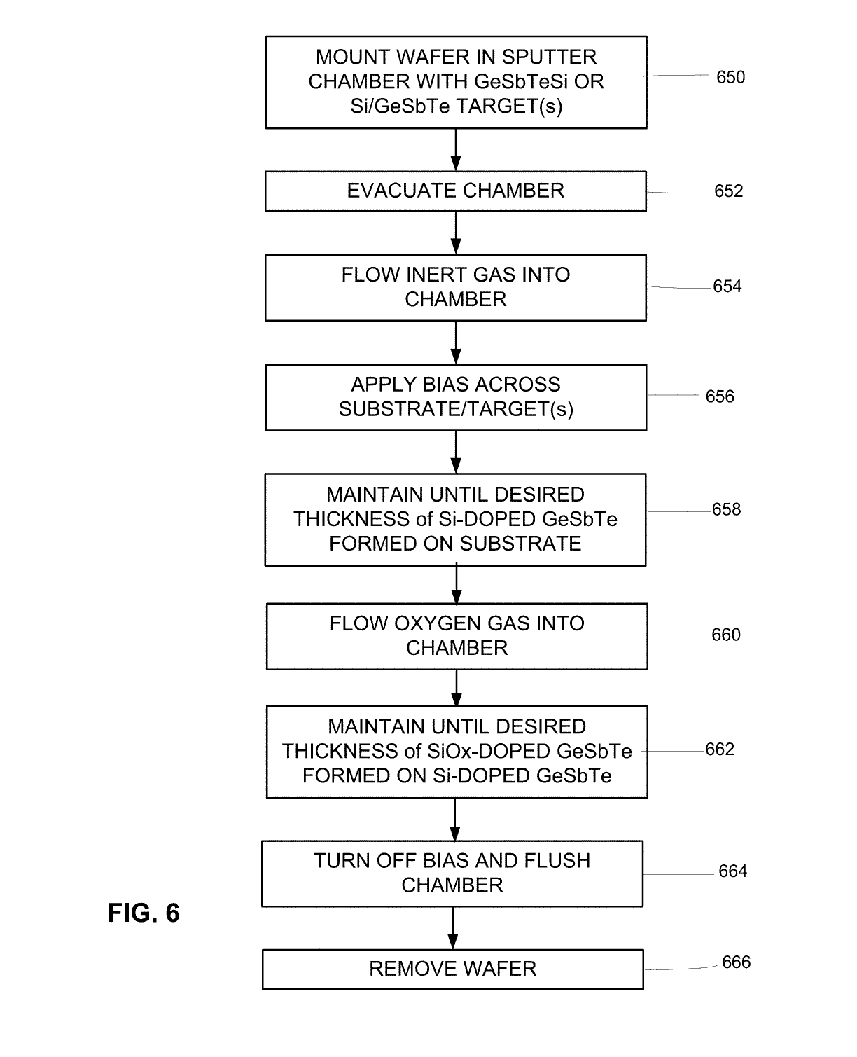

FIG. 6 illustrates a process flow for forming a composite memory element of Si-doped and SiOₓ-doped GeSbTe phase change material using either of the previously described sputtering systems. The process includes first mounting the wafer in a sputter chamber having a Si-GST target, or Si and GST targets (step 650).At this stage, the substrate includes electrodes exposed at a surface of an oxide free layer, such as silicon nitride, in preferred examples. Next, the chamber is evacuated (step 652) to allow for the creation of a flow of ions sputtered from the target source or sources. An inert gas only, such as argon, is flowed into the chamber, to establish an oxygen-free atmosphere suitable for sputtering (step 654). Suitable bias voltages are applied across the substrate and targets, such as a DC bias, to establish an electric field within the sputter chamber necessary to induce the sputtering process (step 656). Optionally, a pre-sputtering interval can be executed to prepare the target before exposing the wafer to the sputtering atmosphere. The conditions for sputtering are maintained with the wafer exposed, for an interval of time, for example 1-10 seconds, sufficient to obtain the desired thickness of Si-doped GeSbTe memory material on the substrate (step 658). In this example, the thickness of Si-doped GeSbTe memory material is about 1 to 10 nm, no greater than 10 nm, preferably about 3 nm. Because an oxygen free atmosphere is used in the chamber, the deposited layer, Si-doped GeSbTe, of memory material is intended to be oxygen-free, and the first electrode surface is not oxidized during this step from an oxygen carrier in the atmosphere.

To begin formation of the second layer, oxygen gas or another oxygen carrier is then flowed into the chamber (step 660) to form a layer of SiOₓ-doped GeSbTe material on the layer of Si-doped GeSbTe material (step 662). The bias is turned off, and the chamber is flushed (step 664). Finally, the wafer or substrate with Si-doped and SiOₓ doped GeSbTe layers is removed (step 666). The two layers can be formed in a single sputter chamber according to this process.

In another embodiment, the bias can be turned off before the oxygen gas is flowed into the chamber, when the flow of the oxygen gas is steady, and then the bias can be turned on to deposit the SiOₓ doped GeSbTe layer (not shown). Also, the second layer can be formed in a different sputter chamber. In yet another embodiment, the second layer can be formed using a sputter target having different composition of phase change material than the sputter target used to form the first layer. In the example, the compositions or relative component concentrations of the first and second layers as deposited could be different.

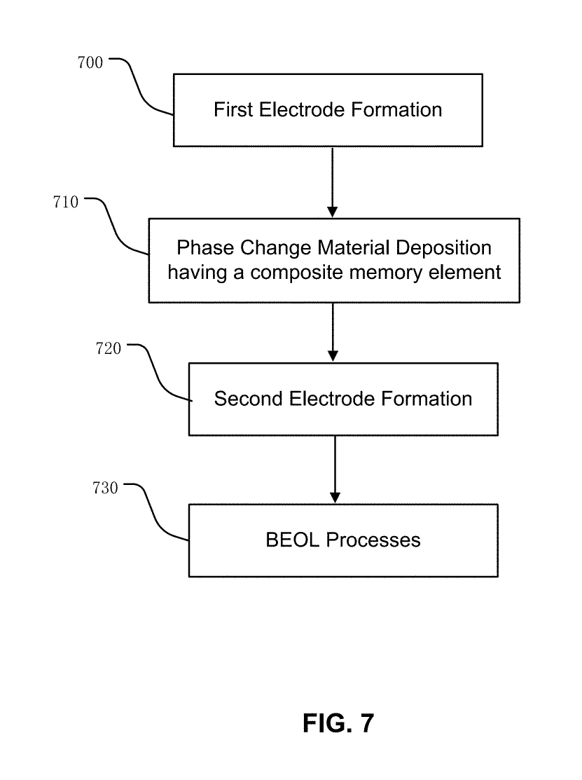

FIG. 7 illustrates a manufacturing process for manufacturing a memory cell having the composite memory element formed in FIG. 6 as described herein, having a structure like that of FIG. 1. Reference numerals applied to elements of the memory cell correspond to those used in FIG. 1.

At step 700 the first electrode 120 having a width or diameter 122 is formed extending through dielectric 130. In the illustrated embodiment, the first electrode 120 comprises TiN, at least at the electrode surface 120A and the dielectric 130 comprises SiN. In some embodiments the first electrode 120 has a sublithographic width or diameter 122.

The first electrode 120 extends through dielectric 130 to underlying access circuitry (not shown). The underlying access circuitry can be formed by standard processes as known in the art, and the configuration of elements of the access circuitry depends upon the array configuration in which the memory cells described herein are implemented. Generally, the access circuitry may include access devices such as transistors and diodes, word lines and sources lines, conductive plugs, and doped regions within a semiconductor substrate.

The first electrode 120 and the dielectric layer 130 can be formed as describe herein. For example, a layer of electrode material can be formed on the top surface of access circuitry (not shown), followed by patterning of a layer of photoresist on the electrode layer using standard photolithographic techniques so as to form a mask of photoresist overlying the location of the first electrode 120. Next the mask of photoresist is trimmed, using for example oxygen plasma, to form a mask structure having sublithographic dimensions overlying the location of the first electrode 120. Then the layer of electrode material is etched using the trimmed mask of photoresist, thereby forming the first electrode 120 having a sublithographic diameter 122. Next dielectric material 130 is formed and planarized.

As another example, the first electrode 120 and dielectric 130 can be formed as described herein. For example, the dielectric 130 can be formed on the top surface of access circuitry followed by sequentially forming an isolation layer and a sacrificial layer. Next, a mask having openings close to or equal to the minimum feature size of the process used to create the mask is formed on the sacrificial layer, the openings overlying the location of the first electrode 120. The isolation layer and the sacrificial layers are then selectively etched using the mask, thereby forming a via in the isolation and sacrificial layers and exposing a top surface of the dielectric layer 130. After removal of the mask, a selective undercutting etch is performed on the via such that the isolation layer is etched while leaving the sacrificial layer and the dielectric layer 130 intact. A fill material is then formed in the via, which, due to the selective undercutting etch process, results in a self-aligned void in the fill material being formed within the via. Next, an anisotropic etching process is performed on the fill material to open the void, and etching continues until the dielectric layer 130 is exposed in the region below the void, thereby forming a sidewall spacer comprising fill material within the via. The sidewall spacer has an opening dimension substantially determined by the dimensions of the void, and thus can be less than the minimum feature size of a lithographic process. Next, the dielectric layer 130 is etched using the sidewall spacers as an etch mask, thereby forming an opening in the dielectric layer 130 having a diameter less than the minimum feature size. Next, an electrode layer is formed within the openings in the dielectric layer 130. A planarizing process, such as chemical mechanical polishing CMP, is then performed to remove the isolation layer and the sacrificial layer and to form the first electrode 120.

At step 710 a phase change element is formed, comprising a composite memory element comprised of a basis phase change material.

The composite memory element can be achieved as previously discussed in FIG. 6. The formation of the first layer in an oxygen-free atmosphere results in no or little oxidation at the electrode surface of the first electrode. Also, other deposition technologies can be applied, including chemical vapor deposition, atomic layer deposition and so on.

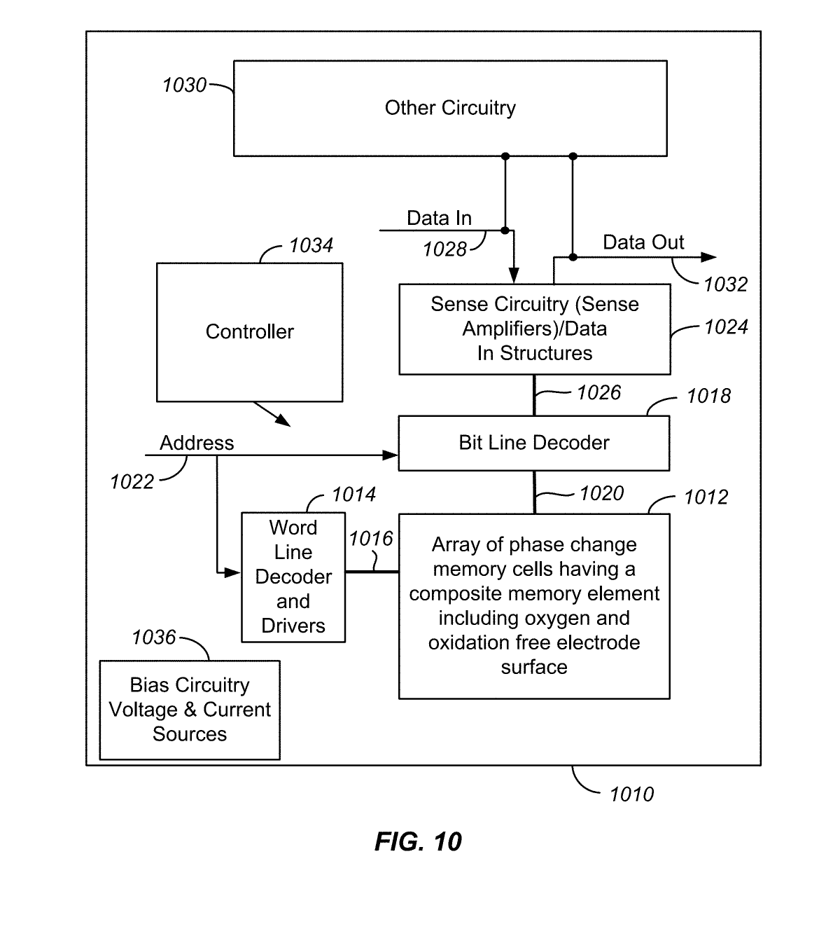

Next, at step 720 a second electrode is formed and at step 730 back-end-of-line (BEOL) processing is performed to complete the semiconductor process steps of the chip, resulting in the structure illustrated in FIG. 1. The BEOL processes can be standard processes as known in the art, and the processes performed depend upon the configuration of the chip in which the memory cell is implemented. Generally, the structures formed by BEOL processes may include contacts, inter-layer dielectrics and various metal layers for interconnections on the chip including circuitry to couple the memory cell to periphery circuitry. These BEOL processes may include deposition of dielectric material at elevated temperatures, such as depositing SiN at 400° C. or high density plasma HDP oxide deposition at temperatures of 500° C. or greater. As a result of these processes, control circuits and biasing circuits as shown in FIG. 10 are formed on the device.

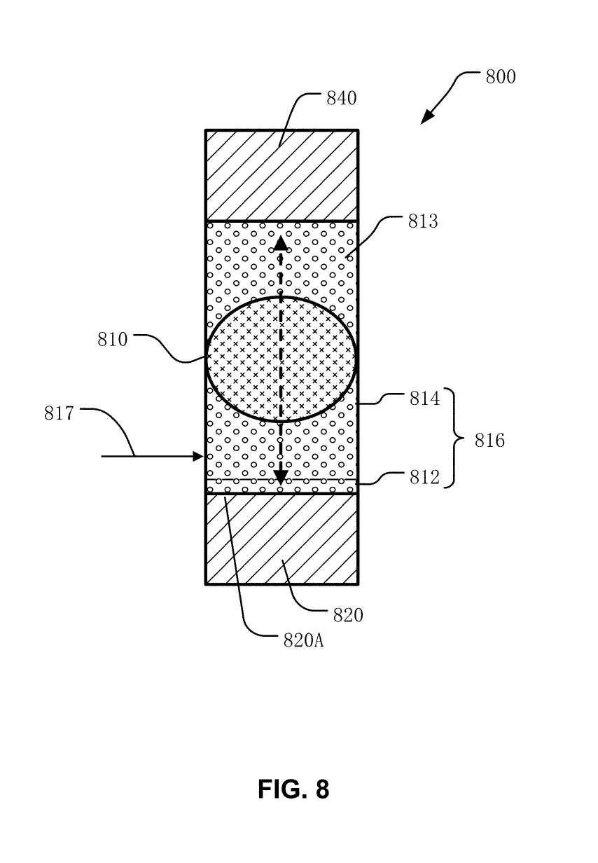

FIG. 8 illustrates a cross-sectional view of a memory cell 800 including a composite memory element 816 with combination of a first layer 812 of Si-doped memory material and a second layer 814 of SiOx-doped memory material. An active region 810 is formed within second layer 814 and an inactive region 813 is the outside the active region 810. The active region 810 can comprise phase change material domains within a dielectric-rich mesh (not shown), caused by separation of the silicon oxide doping from the phase change alloy. In embodiments described herein, the electrode surface 820A is substantially oxide free, as discussed above.

The memory cell 800 includes a pillar-shaped memory element 816 contacting first and second electrodes 820, 840, respectively. The memory element 816 has a width 817 substantially the same as that of the first and second electrodes 820, 840 to define a multi-layer pillar surrounded by dielectric (not shown). As used here, the term “substantially” is intended to accommodate manufacturing tolerances. In operation, as current passes between the first and second electrodes 820, 840 and through the memory element 816, the active region 810 heats up more quickly than the remainder (e.g. inactive region 813) of the memory element.

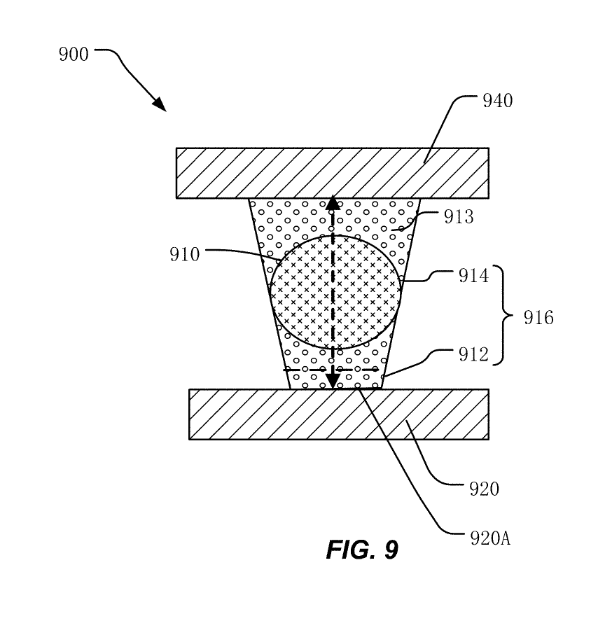

FIG. 9 illustrates a cross-sectional view of a memory cell 900 including a composite memory element 916 consisting of a first layer 912 of Si-doped GST and a second layer 914 of SiOx-doped memory materials. An active region 910 is within second layer 914 and an inactive region 913 outside the active region 910. The active region 910 comprises phase change material domains within a dielectric-rich mesh (not shown), caused by separation of the silicon oxide doping from the phase change alloy.

The memory cell 900 includes a pore-type memory element 916 surrounded by dielectric (not shown) contacting first and second electrodes 920, 940 respectively.

The electrode surface 920A of the first electrode is confined to a relatively small area by the “pore” formed by a cone-shaped opening in this example, in the dielectric layer between the electrodes 920, 940. The memory element 916 includes a first layer 912 formed in an oxygen free atmosphere, and a second layer containing oxygen, such as in the examples described above. In embodiments described herein, the electrode surface 920A is substantially oxide free, as discussed above In operation as current passes between the first and second electrodes and through the memory element the active region heats up more quickly than the remainder of the memory element.

As will be understood, the implementation of the composite memory element described herein are not limited to the memory cell structures described herein and generally include memory cells having an active region comprising phase change material, in which the active region transitions between solid phases having detectable electrical characteristics.

FIG. 10 is a simplified block diagram of an integrated circuit 1010 including a memory array 1012 implemented using memory cells having a composite memory element as described herein. A word line decoder 1014 having read, set and reset modes is coupled to and in electrical communication with a plurality of word lines 1016 arranged along rows in the memory array 1012. The memory array 1012 comprises phase change memory cells having a composite memory element including oxygen (in at least a second layer), and oxidation-free electrode surface. A bit line (column) decoder 1018 is in electrical communication with a plurality of bit lines 1020 arranged along columns in the array 1012 for reading, setting, and resetting the phase change memory cells (not shown) in array 1012. Addresses are supplied on bus 1022 to word line decoder and drivers 1014 and bit line decoder 1018. Sense circuitry (Sense amplifiers) and data-in structures in block 1024, including voltage and/or current sources for the read, set, and reset modes are coupled to bit line decoder 1018 via data bus 1026. Data is supplied via a data-in line 1028 from input/output ports on integrated circuit 1010, or from other data sources internal or external to integrated circuit 1010, to data-in structures in block 1024. Other circuitry 1030 may be included on integrated circuit 1010, such as a general purpose processor or special purpose application circuitry, or a combination of modules providing system-on-a-chip functionality supported by array 1012. Data is supplied via a data-out line 1032 from the sense amplifiers in block 1024 to input/output ports on integrated circuit 1010, or to other data destinations internal or external to integrated circuit 1010.

A controller 1034 implemented in this example, using a bias arrangement state machine, controls the application of bias circuitry voltage and current sources 1036 for the application of bias arrangements including read, program, erase, erase verify and program verify voltages and/or currents for the word lines and bit lines. In addition, bias arrangements for melting/cooling cycling may be implemented as mentioned above. Controller 1034 may be implemented using special-purpose logic circuitry as known in the art. In alternative embodiments, controller 1034 comprises a general-purpose processor, which may be implemented on the same integrated circuit to execute a computer program to control the operations of the device. In yet other embodiments, a combination of special-purpose logic circuitry and a general-purpose processor may be utilized for implementation of controller 1034.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A method of manufacturing a memory device comprising:
forming a first electrode having an electrode surface;
depositing a composite memory element including forming a first layer of memory material on the electrode surface using an oxygen-free atmosphere in a chamber, and forming a second layer of memory material on the first layer in the chamber using an oxygen-containing atmosphere; and
forming a second electrode on the composite memory element.

2. The method of claim 1, wherein the electrode surface of the first electrode is substantially free of oxidation after said forming the second layer of memory material.

3. The method of claim 1, wherein the first layer of memory material comprises a chalcogenide, and the second layer comprises the chalcogenide and oxygen.

4. The method of claim 3, wherein the second layer of memory material includes one or more additives selected from a group including silicon, nitrogen and carbon.

5. The method of claim 1, wherein the first layer has a thickness ranging from about 1 nm to about 10 nm.

5. (canceled)

6. The method of claim 1, including forming the first layer of memory material on the electrode surface by sputtering using an oxygen-free sputter target and the first electrode is disposed in a dielectric layer having an oxide-free surface.

7. The method of claim 6, including forming the second layer by sputtering using the oxygen-free sputter target while flowing an oxygen source gas in the chamber.

8. The method of claim 6, wherein the sputter target comprise a chalcogenide.

9. The method of claim 6, wherein the sputter target comprises a chalcogenide with one or more additives selected from a group including silicon, nitrogen and carbon.

10. The method of claim 1, wherein the first layer of memory material comprises Si-doped GST, and the second layer of memory material comprises SiOₓ-doped GST.

11-20. (canceled)

21. The method of claim 1, wherein oxygen-free atmosphere includes an oxygen-free gas in the chamber, and the first electrode is disposed in a dielectric layer having an oxide-free surface, and including forming the first layer by sputtering.
